(19) United States
(12) Patent Application Publication
(10) Pub. No.: US 2024/0321667 A1
(43) Pub. Date: Sep. 26, 2024

(54) SEMICONDUCTOR PACKAGE

(71) Applicant: SAMSUNG ELECTRONICS CO., LTD., Suwon-si (KR)

(72) Inventors: Seunghun Shin, Suwon-si (KR); Soyeon Kwon, Suwon-si (KR); Unbyoung Kang, Suwon-si (KR); Yeongkwon Ko, Suwon-si (KR)

(73) Assignee: SAMSUNG ELECTRONICS CO., LTD., Suwon-si (KR)

(21) Appl. No.: 18/387,682

(22) Filed: Nov. 7, 2023

(30) Foreign Application Priority Data
Mar. 24, 2023 (KR) 10-2023-0039143
May 10, 2023 (KR) 10-2023-0060702

(51) Int. Cl. H01L 23/31; H01L 21/56; H01L 21/78; H01L 25/00; H01L 25/065; H01L 25/18; H10B 80/00

(52) U.S. Cl. CPC H01L 23/3185; H01L 21/568; H01L 21/78; H01L 25/0657; H01L 25/18; H01L 25/50; H10B 80/00; H01L 23/481; H01L 24/05; H01L 24/06; H01L 24/13; H01L 24/14; H01L 24/16; H01L 24/17; H01L 24/29; H01L 24/32; H01L 24/73; H01L 24/81; H01L 24/94; H01L 24/97; H01L 2224/05554; H01L 2224/0557; H01L 2224/05624; H01L 2224/05644; H01L 2224/05647; H01L 2224/05655; H01L 2224/05669; H01L 2224/05684; H01L 2224/06131; H01L 2224/06136; H01L 2224/06181; H01L 2224/13014; H01L 2224/14131; H01L 2224/14136; H01L 2224/16145; H01L 2224/17181; H01L 2224/2919; H01L 2224/32145; H01L 2224/73204; H01L 2224/73253; H01L 2224/81203; H01L 2224/81815; H01L 2224/94; H01L 2224/97; H01L 2225/06513; H01L 2225/06541; H01L 2924/0665

(57) ABSTRACT

A semiconductor package includes a first semiconductor chip including a first surface and a second surface opposite to the first surface, a second semiconductor chip stacked on the first surface of the first semiconductor chip, and a molding layer contacting the first surface of the first semiconductor chip and a sidewall of the second semiconductor chip. The molding layer includes a first sidewall from a lower end of the first semiconductor chip to a first height in a first direction perpendicular to the first surface of the first semiconductor chip, a second sidewall from the first height to a second height in the first direction, and a flat surface that extends from the first height in a second direction that is parallel with the first surface of the first semiconductor chip.

### CROSS-REFERENCE TO RELATED APPLICATIONS

This application is based on and claims priority under 35 U.S.C. § 119 to Korean Patent Application No. 10-2023-0039143, filed on Mar. 24, 2023 and Korean Patent Application No. 10-2023-0060702, filed on May 10, 2023 in the Korean Intellectual Property Office, the disclosures of each of which being incorporated by reference herein in their entireties.

### BACKGROUND

The present disclosure relates to a semiconductor package and, more particularly, to a semiconductor package having a pre-processing process performed on a surface thereof.

An operation of cutting wafers vertically and horizontally into individual chips is called dicing. There are generally three methods of dicing.

As a first method, there is blade dicing, in which a wafer is cut by rotating a very thin circular blade called a diamond blade at a high speed.

As a second method, there is scribe breaking, in which a wafer is cut by making a scratch or scribe on the wafer by using an edge of a diamond, and then mechanical stress is applied to the wafer to form a break along the scratch or scribe.

As a third method, there is laser dicing, in which a wafer is cut by using a laser beam. Laser dicing is an operation of dividing a wafer into individual chips by concentrating laser energy to sublimate, melt, or ionize a portion of a wafer material.

### SUMMARY

It is an aspect to provide a semiconductor package having improved roughness by performing a pre-processing process on a surface thereof.

It is another aspect to provide a semiconductor package including a semiconductor chip facilitating a singulation process.

According to an aspect of one or more embodiments, there is provided a semiconductor package comprising a first semiconductor chip including a first surface and a second surface opposite to the first surface; at least one second semiconductor chip stacked on the first surface of the first semiconductor chip; and a molding layer contacting the first surface of the first semiconductor chip and a sidewall of the at least one second semiconductor chip, wherein the molding layer comprises a first sidewall from a lower end of the first semiconductor chip to a first height in a first direction perpendicular to the first surface of the first semiconductor chip; a second sidewall from the first height to a second height in the first direction; and a flat surface that extends from the first height in a second direction that is parallel with the first surface of the first semiconductor chip.

According to another aspect of one or more embodiments, there is provided a semiconductor package comprising a first semiconductor chip including a first surface and a second surface opposite to the first surface, the first semiconductor chip including a plurality of first through electrodes; at least one second semiconductor chip stacked on the first surface of the first semiconductor chip, and including a plurality of second through electrodes that are electrically connected to the plurality of first through electrodes, respectively; an interposer arranged on a first region of the second surface of the first semiconductor chip; and an oxide layer arranged in a second region of the second surface of the first semiconductor chip, where the interposer is not arranged, wherein the oxide layer contacts with a sidewall of the interposer.

According to yet another aspect of one or more embodiments, there is provided a semiconductor package comprising a package substrate; an interposer on the package substrate; a first semiconductor device mounted on the interposer; a second semiconductor device mounted on the interposer and spaced apart from the first semiconductor device, the second semiconductor device being electrically connected to the first semiconductor device via the interposer; and a package molding layer arranged on the interposer, and covering a sidewall of the first semiconductor device and a sidewall of the second semiconductor device. The first semiconductor device comprises a first semiconductor chip including a first surface and a second surface opposite to the first surface, at least one second semiconductor chip mounted on the first semiconductor chip, and a molding layer covering the first surface of the first semiconductor chip and a sidewall of the at least one second semiconductor chip. The molding layer comprises a first sidewall from a lower end of the first semiconductor chip to a first height in a first direction that is perpendicular to the first surface of the first semiconductor chip, a second sidewall from the first height to a second height in the first direction, and a flat surface that extends at the first height in a second direction that is parallel with the first surface of the first semiconductor chip.

### BRIEF DESCRIPTION OF THE DRAWINGS

Various embodiments will be more clearly understood from the following detailed description taken in conjunction with the accompanying drawings, in which:

FIG. 1A is a cross-sectional view of a semiconductor package according to an embodiment;

FIG. 1B is a bottom view of the semiconductor package illustrated in FIG. 1A;

FIGS. 2A through 2L are cross-sectional views illustrating a method of manufacturing a semiconductor package, according to various embodiments;

FIGS. 3A through 3C are cross-sectional views illustrating a method of manufacturing a semiconductor package, according to various embodiments;

FIG. 4 is a cross-sectional view of a semiconductor package according to an embodiment; and

FIGS. 5A through 5C are cross-sectional views illustrating a method of manufacturing a semiconductor package, according to various embodiments.

### DETAILED DESCRIPTION

Hereinafter, various embodiments are described in detail with reference to accompanying diagrams. Identical reference numerals are used for the same constituent devices across the drawings, and duplicate descriptions thereof are omitted for conciseness.

Because various changes may be applied to the embodiments and embodiments consistent with the present disclosure may have various modifications, particular embodiments are illustrated in the diagrams and described in detail. However, this description is not intended to limit the present disclosure to particular modes of practice, and it is to be appreciated that all changes, equivalents, and substitutes, which do not depart from the spirit and technical scope of the present disclosure, are encompassed in the appended claims. In the description of the embodiments, certain detailed explanations of the related art are omitted when it is deemed that such certain detailed explanations may unnecessarily obscure the embodiments.

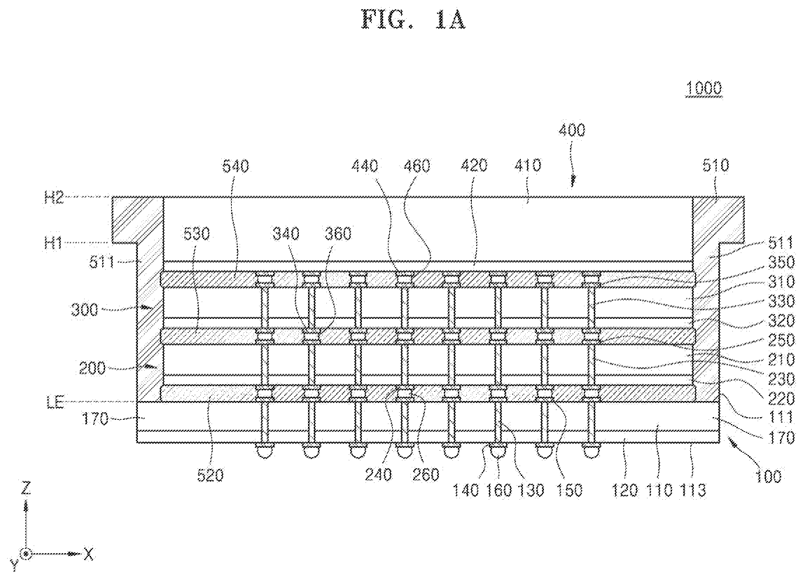

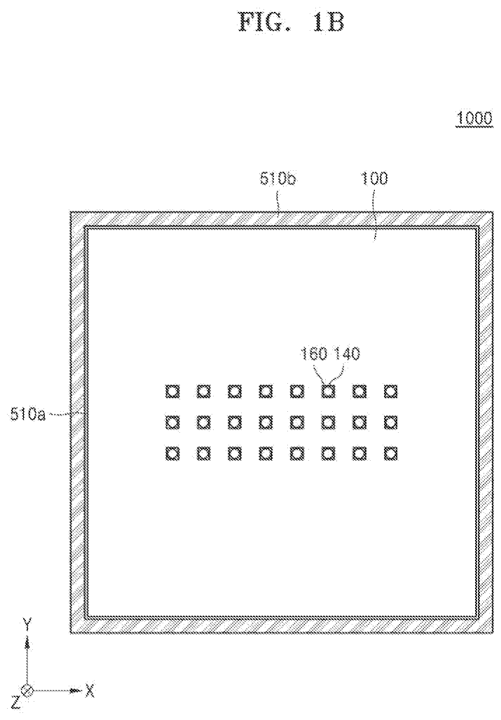

FIG. 1A is a cross-sectional view of a semiconductor package according to an embodiment. FIG. 1B is a bottom-section view of the semiconductor package illustrated in FIG. 1A.

Referring to FIGS. 1A and 1B, a semiconductor package 1000 may include a plurality of semiconductor chips stacked in a vertical direction. For example, the semiconductor package 1000 may include a first semiconductor chip 100, a second semiconductor chip 200, a third semiconductor chip 300, and a fourth semiconductor chip 400, which are vertically stacked.

For example, a horizontal cross-sectional area of the first semiconductor chip 100 may be greater than a horizontal cross-sectional area of each of the second through fourth semiconductor chips 200 through 400, and the horizontal cross-sectional area of each of the second through fourth semiconductor chips 200 through 400 may be generally the same. As illustrated in FIG. 1A, the second through fourth semiconductor chips 200 through 400 may overlap the first semiconductor chip 100 in the vertical direction.

In some embodiments, the first through fourth semiconductor chips 100 through 400 may include semiconductor chips of the same type. For example, the first through fourth semiconductor chips 100 through 400 may include memory chips. The memory chip may include a volatile memory semiconductor chip, such as dynamic random access memory (RAM) (DRAM) and static RAM (SRAM), or a non-volatile memory chip, such as phase-change RAM (PRAM), magneto-resistive RAM (MRAM), ferroelectric RAM (FeRAM), and resistive RAM (RRAM).

In some embodiments, the first through fourth semiconductor chips 100 through 400 may include semiconductor chips of different types from each other. For example, some of the first through fourth semiconductor chips 100 through 400 may include logic chips, and the other of the first through fourth semiconductor chips 100 through 400 may include memory chips. For example, the logic chip may include a central processing unit (CPU) chip, a graphics processing unit (GPU) chip, or an application processor (AP) chip.

In some embodiments, the first through fourth semiconductor chips 100 through 400 may be implemented based on a high bandwidth memory (HBM) standard or a hybrid memory cube (HMC) standard. In this case, the first semiconductor chip 100 at the lowermost layer may function as a buffer die, and the second through fourth semiconductor chips 200 through 400 may function as core dies. For example, the buffer die may also be referred to as an interface die, a base die, a logic die, a master die, or the like, and the core die may also be referred to as a memory die, a slave die, etc. FIGS. 1A and 1B illustrate that the semiconductor package 1000 includes three core dies, but the number of core dies may be variously changed. For example, the semiconductor package 1000 may include four, eight, twelve, or sixteen core dies.

The first semiconductor chip 100 may include a first semiconductor substrate 110, a first semiconductor device layer 120, and a first through electrode 130.

In some embodiments, the first semiconductor substrate 110 may include, for example, silicon (Si). In some embodiments, the first semiconductor substrate 110 may include a semiconductor element such as germanium (Ge), or a compound semiconductor, such as silicon carbide (SiC), gallium arsenide (GaAs), indium arsenide (InP), and indium phosphide (InP). The first semiconductor substrate 110 may include a conductive region, for example, a well doped with impurities or a structure doped with impurities. The first semiconductor substrate 110 may have various device isolation structures such as a shallow trench isolation (STI) structure.

The first semiconductor device layer 120 may include a plurality of individual devices of various types and an interlayer insulating layer (not illustrated). The plurality of individual devices may include various microelectronic devices, for example, a metal-oxide-semiconductor transistor (MOSFET) such as complementary metal-oxide semiconductor (CMOS) transistor, large scale integration (LSI), a flash memory, DRAM, SRAM, electrically erasable programmable ROM (EEPROM), PRAM, MRAM, RRAM, an image sensor such as a CMOS imaging sensor (CIS), a micro-electro-mechanical system (MEMS), an active element, a passive element, etc. The plurality of individual devices may be electrically connected to the conductive region of the first semiconductor substrate 110. The first semiconductor device layer 120 may further include a conductive wiring or a conductive plug, which electrically connects at least two of the plurality of individual devices to each other, or which electrically connects the plurality of individual devices to the conductive region of the first semiconductor substrate 110.

The first through electrode 130 may at least partially penetrate the first semiconductor substrate 110, and may further at least partially penetrate the first semiconductor device layer 120. The first through electrode 130 may be configured to electrically connect a first upper connection pad 150 arranged on a first surface 111 of the first semiconductor chip 100 to a first lower connection pad 140 arranged on a second surface 113 opposite to the first surface 111 of the first semiconductor chip 100. The first through electrode 130 may include a buried conductive layer of a cylindrical shape and a conductive barrier layer of a cylindrical shape surrounding sidewalls of the buried conductive layer. The buried conductive layer may include at least one material of copper (Cu), tungsten (W), nickel (Ni), and cobalt (Co). The conductive barrier layer may include at least one material of Ti, TiN, Ta, TaN, Ru, Co, Mn, WN, Ni, and NiB. A via insulating layer may be arranged between the first semiconductor substrate 110 and the first through electrode 130. The via insulating layer may include an oxide layer, a nitride layer, a carbide layer, a polymer, or a combination thereof.

The first lower connection pad 140 may be provided on the second surface 113 of the first semiconductor chip 100. For example, the first lower connection pad 140 may be arranged on the first semiconductor device layer 120, and may be electrically connected to the first through electrode 130. The first lower connection pad 140 may include at least one of aluminum (Al), Cu, Ni, W, platinum (Pt), and gold (Au).

A first connection bump 160 may be provided on the first lower connection pad 140. The first connection bump 160 may be arranged on a lowermost bottom surface of the semiconductor package 1000, and may include a bump for mounting the semiconductor package 1000 on an external substrate or interposer. The first connection bump 160 may receive from the outside of the semiconductor package 1000 at least one of a control signal, a power signal, or a ground signal for operations of the first through fourth semiconductor chips 100 through 400, or may receive from the outside a data signal for operations of the first through fourth semiconductor chips 100 through 400, or may be used as an electrical path that provides data stored in the first through fourth semiconductor chips 100 through 400 to the outside.

The first upper connection pad 150 may be provided on the first surface 111 of the first semiconductor chip 100. The first upper connection pad 150 may include at least one of Al, Cu, Ni, W, Pt, and Au.

The second semiconductor chip 200 may be mounted on the first surface 111 of the first semiconductor chip 100. The first semiconductor chip 100 may be electrically connected to the second semiconductor chip 200 via a second connection bump 260. Between the first semiconductor chip 100 and the second semiconductor chip 200, a first insulating adhesive layer 520 that surrounds the second connection bump 260 may be arranged. The first insulating adhesive layer 520 may include, for example, a non-conductive film (NCF), a non-conductive paste (NCP), insulating polymer, or epoxy resin.

The second semiconductor chip 200 may include a second semiconductor substrate 210, a second semiconductor device layer 220, a second through electrode 230, a second upper connection pad 250, and a second lower connection pad 240. Because the second semiconductor chip 200 may have characteristics substantially the same as or similar to those of the first semiconductor chip 100, a detailed description of the second semiconductor chip 200 is omitted for conciseness.

The third semiconductor chip 300 may be mounted on the second semiconductor chip 200, and may include a third semiconductor substrate 310, a third semiconductor device layer 320, a third through electrode 330, a third upper connection pad 350, and a third lower connection pad 340. The second semiconductor chip 200 may be electrically connected to the third semiconductor chip 300 via a third connection bump 360, and a second insulating adhesive layer 530 surrounding the third connection bump 360 may be arranged between the second semiconductor chip 200 and the third semiconductor chip 300. Because the third semiconductor chip 300 may have substantially similar characteristics to the first semiconductor chip 100, a detailed description of the third semiconductor chip 300 is omitted for conciseness.

The fourth semiconductor chip 400 may be mounted on the third semiconductor chip 300, and may include a fourth semiconductor substrate 410, a fourth semiconductor device layer 420, and a fourth lower connection pad 440. The third semiconductor chip 300 may be electrically connected to the fourth semiconductor chip 400 via a fourth connection bump 460, and a third insulating adhesive layer 540 surrounding the fourth connection bump 460 may be arranged between the third semiconductor chip 300 and the fourth semiconductor chip 400. The fourth semiconductor chip 400 may have similar characteristics to the first semiconductor chip 100, except that the fourth semiconductor chip 400 does not include a through electrode, and thus, a detailed description of the fourth semiconductor chip 400 is omitted for conciseness.

While the first through electrode 130, the first upper connection pad 150, the first lower connection pad 140, the first connection bump 160, the second connection bump 260, the second through electrode 230, the second upper connection pad 250, the second lower connection pad 240, the third through electrode 330, the third upper connection pad 350, the third lower connection pad 340, the third connection bump 360, the fourth lower connection pad 440, and the fourth connection bump 460 are described above in the singular, each component is provided in plural as shown in FIG. 1A and the respective descriptions above apply equal to the remaining ones of the plural components.

The semiconductor package 1000 may include a molding layer 510 that contacts sidewalls of the second through fourth semiconductor chips 200 through 400 and that contacts the first surface 111 of the first semiconductor chip 100. The molding layer 510 may cover side surfaces of the first insulating adhesive layer 520, the second insulating adhesive layer 530, and the third insulating adhesive layer 540 that protrude in a horizontal direction (X and/or Y directions) from sidewalls of the second to fourth semiconductor chips 200 to 400.

In some embodiments, the molding layer 510 may include insulating polymer or epoxy resin. For example, the molding layer 510 may include epoxy mold compound (EMC). In some embodiments, the molding layer 510 may include a light transmitting material.

The molding layer 510 may include a sidewall 511 that extends in a first direction (for example, a Z direction) perpendicular to the first surface 111 of the first semiconductor chip 100. In some embodiments, the sidewall 511 of the molding layer 510 may have a profile that extends from a lower end LE of the first semiconductor chip 100 to a first height H1 in the Z direction (not illustrated), and may have a profile that extends from the first height H1 to a second height H2 in the Z direction (not illustrated). The sidewall 511 of the molding layer 510 may include a first portion and a second portion. The first portion may extend from the lower end LE of the first semiconductor chip 100 to the first height H1. The second portion may extend from the first height H1 to the second height H2. Here, the second portion may protrude more to an external side of the first semiconductor chip 100 than the first portion. In other words, the sidewall 511 may be formed in a one-column stair shape similar to an ‘L’ shape. In some embodiments, the second height may correspond to the height of an upper surface of the molding layer 510.

In some embodiments, with respect to a second direction (for example, X direction or Y direction) in parallel with the first surface 111 of the first semiconductor chip 100, the width of the upper surface of the molding layer 510 in the second direction (for example, X direction or Y direction) may be greater than the width of a lower surface of the molding layer 510 in the second direction (for example, X direction or Y direction). That is, the width of the second portion may be greater than the width of the first portion. In some embodiments, the width of the molding layer 510 in the second direction (for example, X direction or Y direction) may be greater than the length of the first portion from the lower end of the sidewall 511 to the first height in the Z direction. For example, as illustrated in FIG. 1A, the cross-section of the molding layer 510 taken in the vertical direction may have an ‘L’ shape.

The first semiconductor chip 100 may include a sidewall 170 that extends in parallel with the first direction (for example, Z direction). In some embodiments, the sidewall 170 of the first semiconductor chip 100 and the sidewall 511 of the molding layer 510 may have a profile extending to be integrally connected on the same plane at the point where the sidewall 170 of the first semiconductor chip 100 and the sidewall 511 of the molding layer 510 meet each other. In other words, the sidewall 170 and the sidewall 511 may be coplanar in some embodiments.

The sidewall 170 of the first semiconductor chip 100 may be connected to the sidewall 511 of the molding layer 510. In some embodiments, the sidewall 511 of the molding layer 510 and the sidewall 170 of the first semiconductor chip 100 may constitute the entire sidewall of the semiconductor package 1000.

Because the sidewall 511 of the molding layer 510 and the sidewall 170 of the first semiconductor chip 100 constituting the sidewall of the semiconductor package 1000 extend in a step shape similar to the ‘L’ shape with respect to the first direction (for example, Z direction), the sidewall of the semiconductor package 1000 may extend in a step shape similar to the ‘L’ shape with respect to the first direction (for example, Z direction). For example, the width of the semiconductor package 1000 in the second direction (for example, X direction or Y direction) may be formed greater on the upper portion than the bottom portion with respect to the first height, and the cross-section of the semiconductor package 1000 taken in the vertical direction may have an ‘L’ shape.

As illustrated in FIG. 1A, when the semiconductor package 1000 has a vertical cross-section of an ‘L’ shape, the upper end of the sidewall of the semiconductor package 1000 may protrude outwardly more than the lower end of the sidewall of the semiconductor package 1000.

The bottom surface view of the semiconductor package 1000 of FIG. 1B illustrates that lengths and widths formed in the X direction and in the Y direction of both a portion 510a having undergone a surface treatment process that is, a roughness-formed region, and a portion 510b having not undergone the surface treatment process, are conformally formed, but embodiments are not limited thereto, and various modifications and changes may be made within the scope of the technical idea of the present disclosure. The portion 510a having undergone the surface treatment process is not limited in any direction, and the ratio and an arrangement method thereof with respect to the portion 510b having not undergone the surface treatment process are not limited to the example illustrated in the drawings.

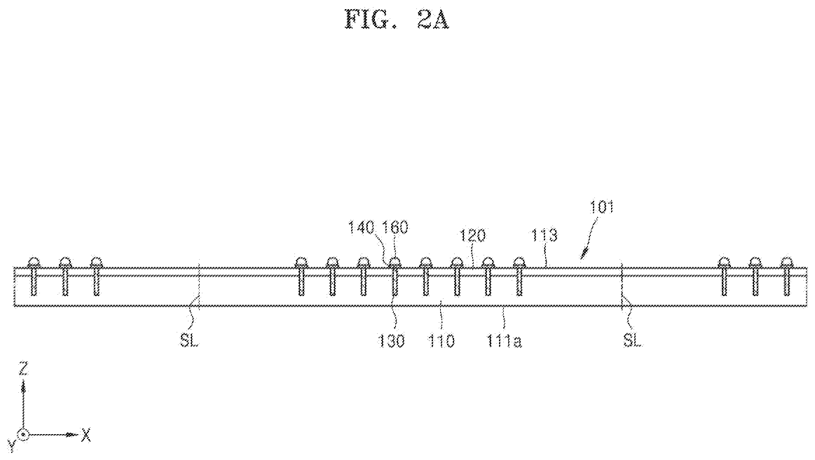

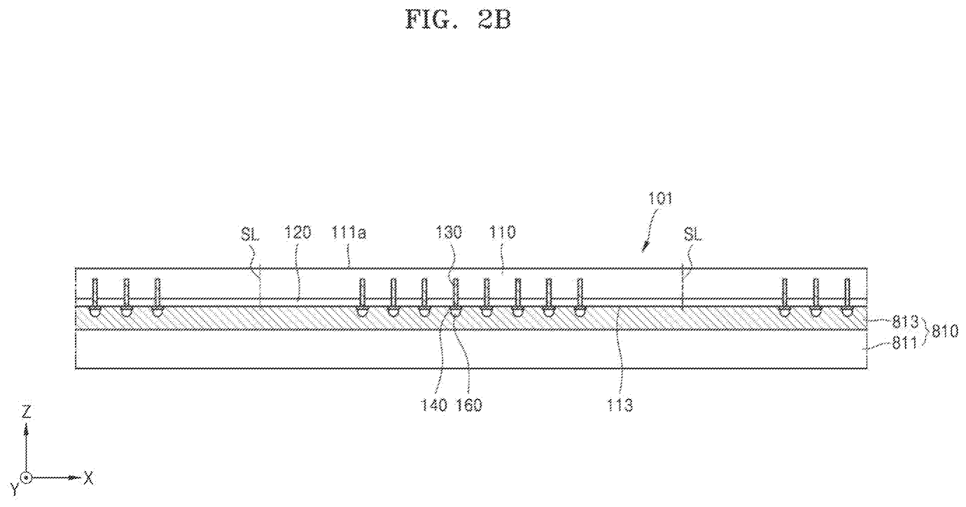

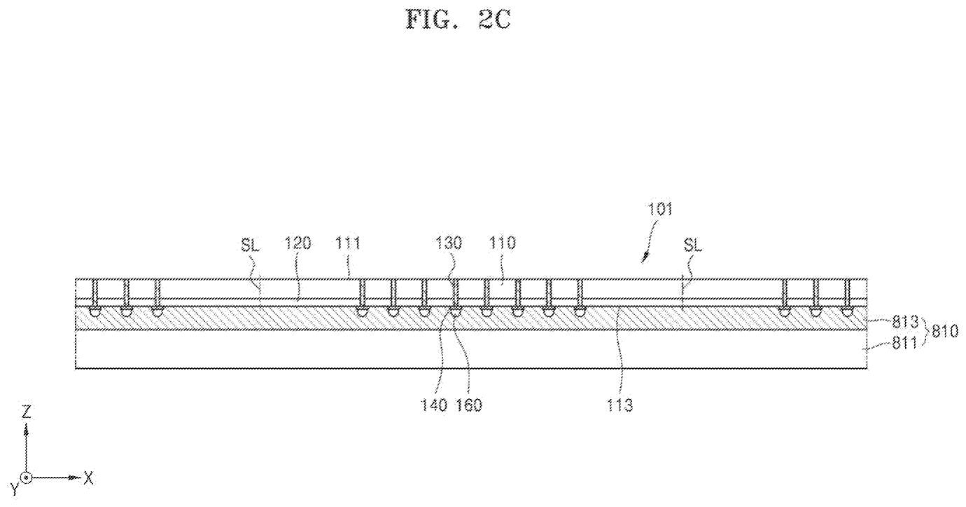

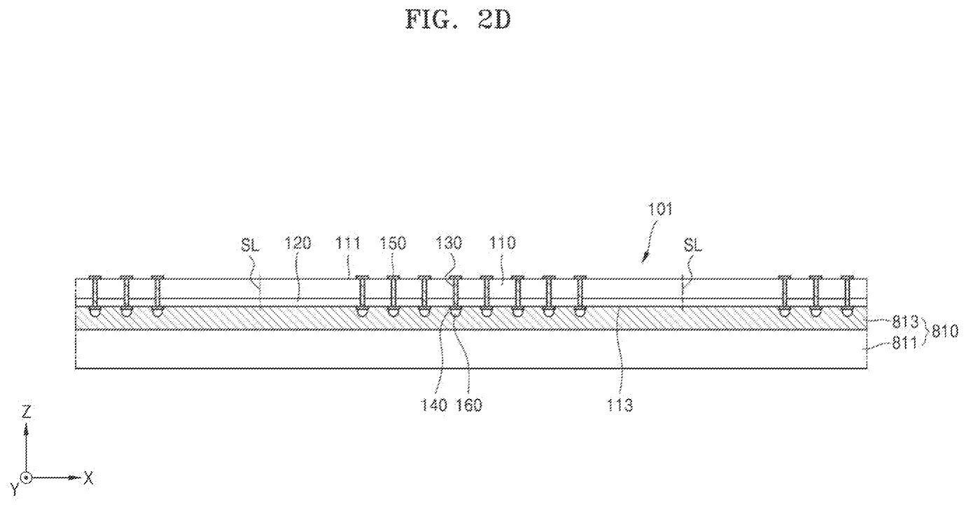

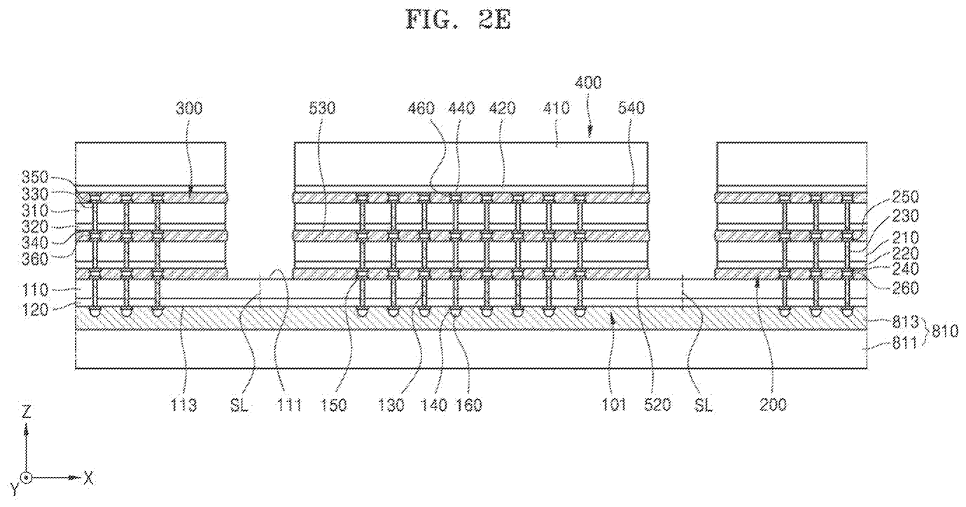

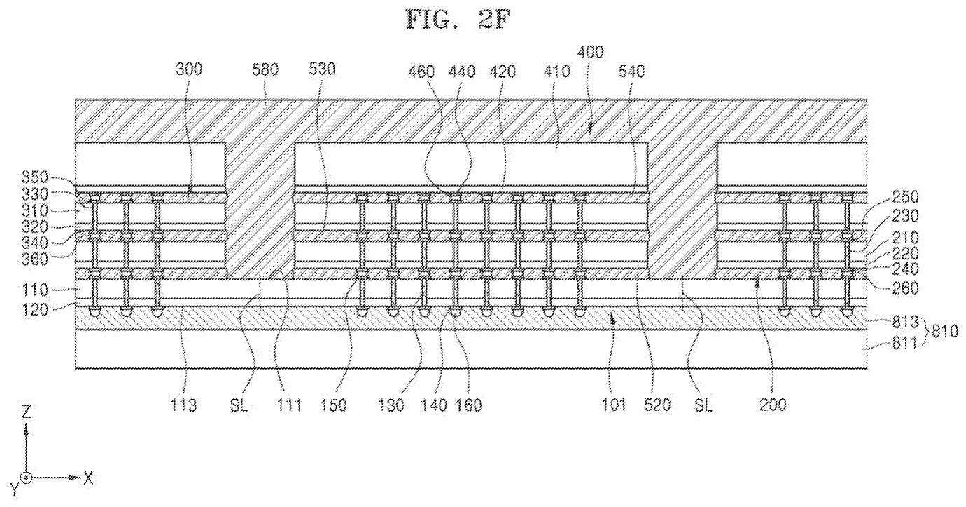

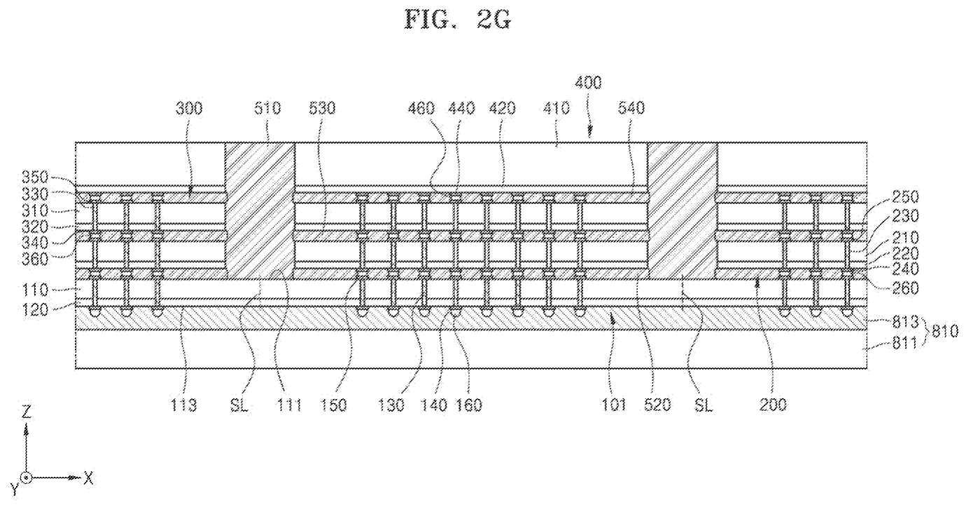

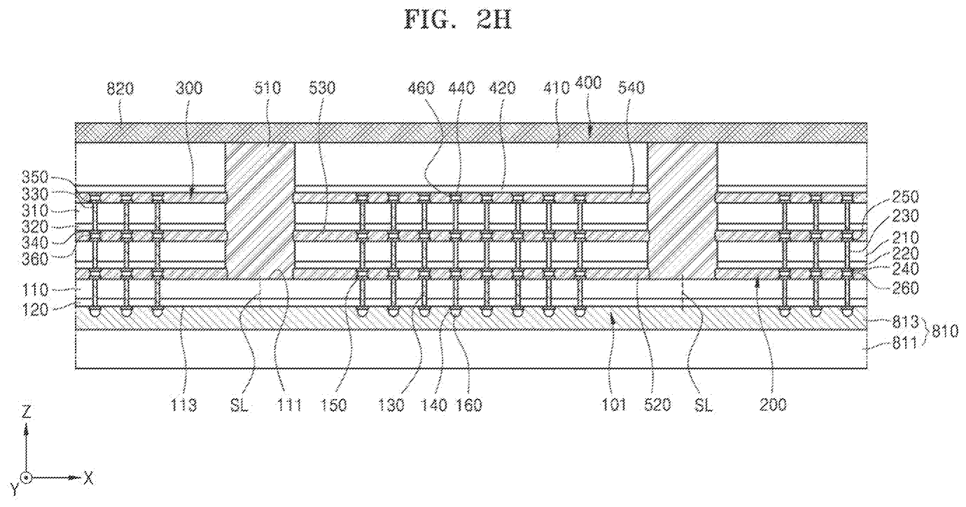

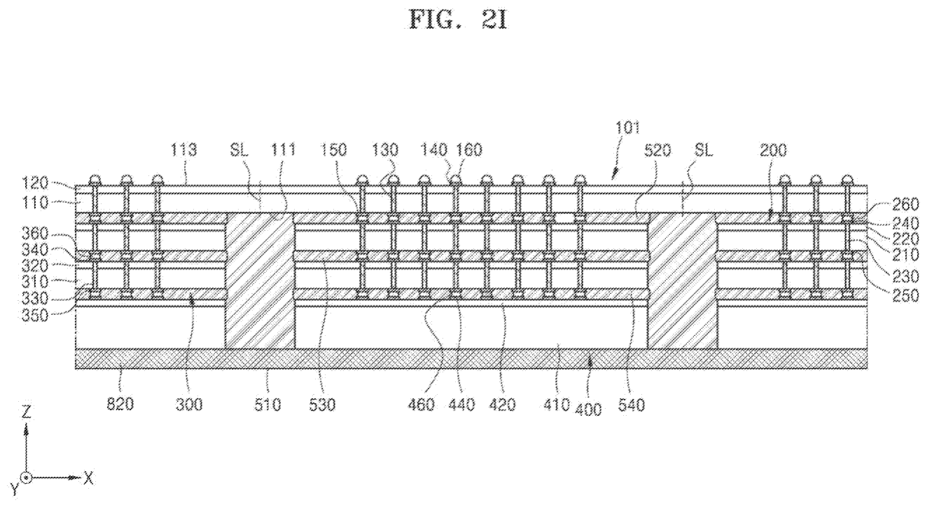

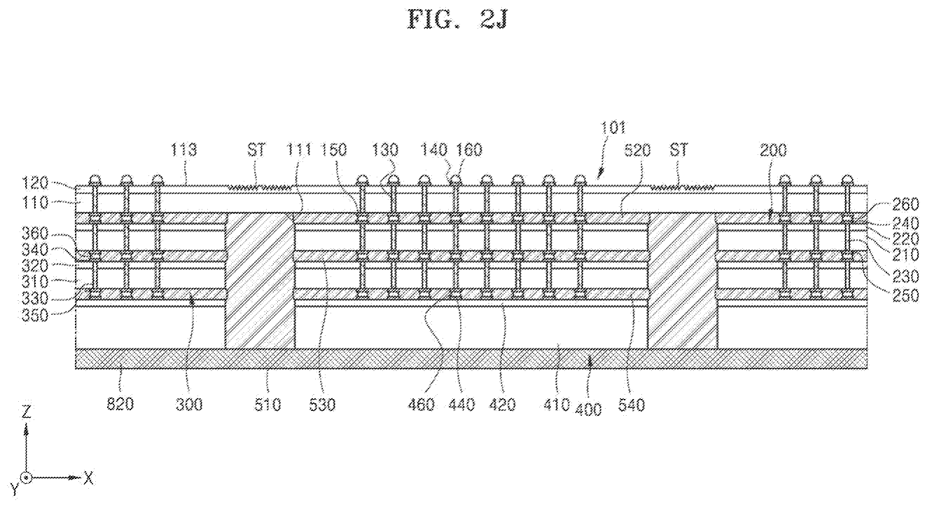

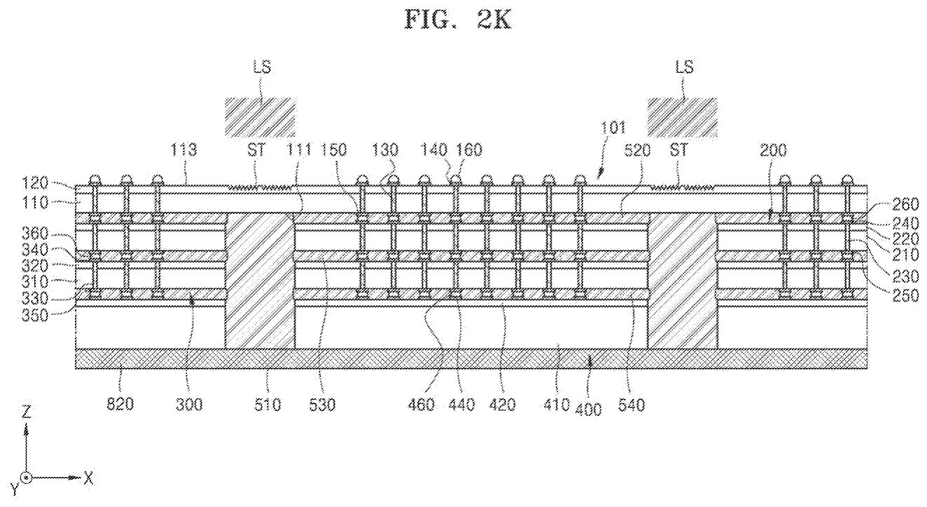

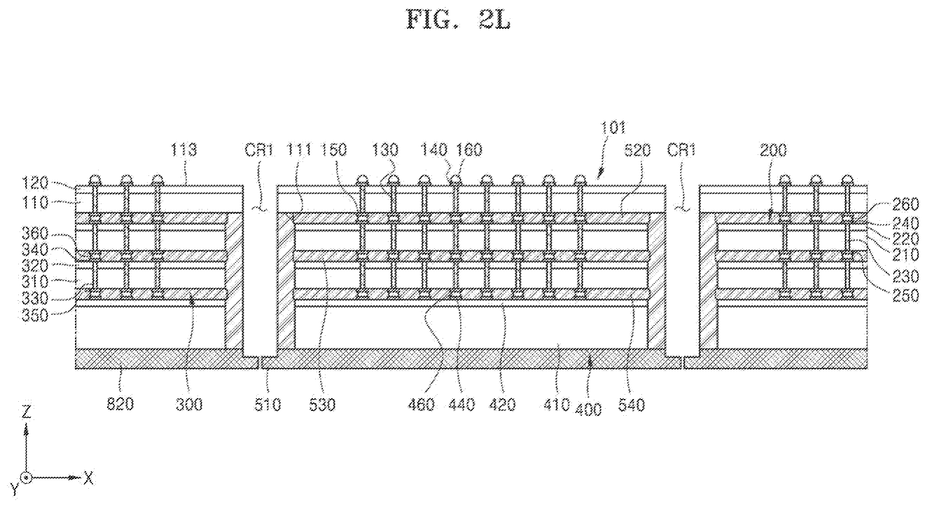

FIGS. 2A through 2I are cross-sectional views illustrating a method of manufacturing the semiconductor package 1000, according to various embodiments. Hereinafter, the method of manufacturing the semiconductor package 1000 illustrated in FIGS. 1A and 1B is described with reference to FIGS. 2A through 2L.

Referring to FIG. 2A, a first semiconductor wafer 101 may be prepared. The first semiconductor wafer 101 may include a plurality of semiconductor devices to be divided by a scribe lane SL. The semiconductor device may include the first semiconductor substrate 110 including a frontside surface and a backside surface opposite to the frontside surface, the first semiconductor device layer 120 formed on the frontside surface of the first semiconductor substrate 110, and the first through electrode 130. The first lower connection pad 140 electrically connected to the first through electrode 130 may be formed on the frontside surface of the first semiconductor substrate 110, and the first connection bump 160 may be formed on the first lower connection pad 140.

Referring to FIG. 2B, the first semiconductor wafer 101, on which the first connection bump 160 is formed, may be attached to a first carrier substrate 810. The first carrier substrate 810 may include a support substrate 811 and an adhesive material 813 on the support substrate 811. The second surface 113 of the first semiconductor wafer 101 may be in contact with the first carrier substrate 810, and a first surface 111a of the first semiconductor wafer 101 may be exposed upwardly.

Referring to FIG. 2C, a portion of the first semiconductor substrate 110 may be removed and a portion of the first through electrode 130 may be exposed. As a result of removing the portion of the first semiconductor substrate 110, the first through electrode 130 may have a shape of penetrating the first semiconductor substrate 110. To expose the first through electrode 130, a portion of the first semiconductor substrate 110 may be removed by using a chemical mechanical polishing (CMP) process, an etch-back process, or a combination thereof.

Referring to FIG. 2D, the first upper connection pad 150 electrically connected to the first through electrode 130 may be formed on the first surface 111 of the first semiconductor wafer 101.

Referring to FIG. 2E, second semiconductor chips 200 may be stacked on the first surface 111 of the first semiconductor wafer 101. The second semiconductor chips 200 may be arranged to be apart from each other in the horizontal direction on the first surface 111 of the first semiconductor wafer 101. The second semiconductor chips 200 may be manufactured by processing a semiconductor wafer in a process similar to the processes in FIGS. 2A through 2D, and by cutting the processed semiconductor wafer into individual chips.

The second semiconductor chip 200 may be stacked on the first semiconductor wafer 101 so that the first through electrode 130 is electrically connected to the second through electrode 230. The second semiconductor chip 200 may be stacked on the first semiconductor wafer 101, so that the first through electrode 130 is electrically connected to the second through electrode 230, and so that the second connection bump 260 of the second semiconductor chip 200 contacts the first upper connection pad 150. The first insulating adhesive layer 520 may be formed between the first semiconductor wafer 101 and the second semiconductor chip 200. The first insulating adhesive layer 520 may be formed to be surrounded by the second connection bump 260 between the first semiconductor wafer 101 and the second semiconductor chip 200. The first insulating adhesive layer 520 may include, for example, the NCF.

For example, to stack the second semiconductor chip 200 on the first semiconductor wafer 101, a reflow process or a thermal compression process may be performed. The adhesion force between the second connection bump 260 and the second lower connection pad 240 may be strengthened by using the reflow process or the thermal compression process.

After stacking the second semiconductor chips 200 on the first semiconductor wafer 101, by using a stacking method and a similar method thereto of the second semiconductor chips 200, third semiconductor chips 300 may be stacked on the second semiconductor chips 200, and the fourth semiconductor chips 400 may be stacked on the third semiconductor chips 300.

Referring to FIG. 2F, a preliminary molding layer 580 that molds the second through fourth semiconductor chips 200 through 400 on the first semiconductor wafer 101 may be formed. To form the preliminary molding layer 580, an appropriate amount of molding material may be provided on the first semiconductor wafer 101, and the molding material may be cured by using a curing process.

Referring to FIGS. 2F and 2G, a portion of the preliminary molding layer 580 may be removed by using a planarization process such as CMP until an upper surface of the fourth semiconductor chip 400 is exposed. By using the planarization process, a portion of the fourth semiconductor chip 400 may also be removed together with a portion of the preliminary molding layer 580. As a result of removing a portion of the preliminary molding layer 580, the molding layer 510 covering the upper surface of the first semiconductor wafer 101 and the sidewalls of the second through fourth semiconductor chips 200 through 400 while exposing the upper surface of the fourth semiconductor chip 400 may be formed.

Referring to FIG. 2H, onto the upper surface of the molding layer 510 and the upper surface of the fourth semiconductor chip 400, which have been planarized, a second carrier substrate 820 may be attached. For example, the second carrier substrate 820 may include a dicing film.

Referring to FIG. 2I, after reversing the resultant product of FIG. 2H, the first carrier substrate 810 may be removed. When the first carrier substrate 810 is removed, the second surface 113 of the first semiconductor wafer 101 may be exposed.

Referring to FIG. 2J, before a sawing process of cutting the resultant product of FIG. 2I is performed, a surface treatment process may be additionally performed along the periphery of the scribe lane SL of the first semiconductor wafer 101. The surface treatment process may be selectively performed only on a portion where the sawing process is to be performed. The surface treatment process may be performed to increase the illuminance of the surface. In some embodiments, the surface roughness may be improved from a nanometer level to a micrometer level by the surface treatment process, and thus may be improved by approximately 1000 times or more. Due to the surface treatment process, the permeability of the surface may decrease. In some embodiments, the surface treatment process may be performed by a dicing blade or a grinder. Referring to FIG. 1B together with FIG. 2J, the portion 510b that has not been treated by the surface treatment process may be formed flat, but the portion 510a that has been treated by the surface treatment process may not be formed flat and may have a rough surface.

Referring to FIGS. 2K and 2L, a sawing process may be performed along the scribe lane SL on the resultant product, on which the surface treatment process in FIG. 2J has been performed. The sawing process may be performed by using laser LS. Because the surface treatment process has been performed in FIG. 2J, the material constituting the molding layer 510 may be in a state of reduced permeability. Accordingly, the irradiating laser LS may process the molding layer 510 from the frontside surface.

According to the technical idea of the present disclosure, because the molding layer 510 is processed from the frontside surface, peeling or cracking due to the reduction in the interface adhesion between the molding layer 510 and a chip may be improved, and the singulation quality of the chip may be improved.

The resultant product of FIG. 2L by using the manufacturing process of the semiconductor package 1000 described with reference to FIGS. 2A through 2K may be separated into the semiconductor packages 1000 each including the first through fourth semiconductor chips 100 through 400, as illustrated in FIG. 1A. After separating the semiconductor packages 1000 by using the sawing process, the second carrier substrate 820 may be removed.

In some embodiments, the sawing process may include a laser cutting process of cutting a kerf target by using the laser LS generated by a laser irradiation device. The laser cutting process may cut, by using the laser LS, the resultant product of FIG. 2K from the second surface 113 of the first semiconductor wafer 101 to the bottom surface of the molding layer 510 in contact with the second carrier substrate 820 along the scribe lane SL of the first semiconductor wafer 101.

The laser cutting process may form a cutting region CR1 formed in parallel with the irradiation direction of the laser LS. In other words, the cutting region CR1 may have a rectangular shape. Accordingly, the sidewalls of the semiconductor packages 1000 separated by the laser cutting process may be formed to have an inclination. As a result of cutting the resultant product of FIG. 2K by performing the laser cutting process after increasing the surface roughness, the process yield by using the singulation process of the semiconductor package 1000 may be improved.

Because the surface treatment process for increasing the surface roughness and reducing the permeability of a portion, on which the cutting process is to be performed, has been performed before the laser cutting process is performed, the laser cutting process may manufacture the semiconductor package 1000 having reduced generation of defects such as a crack. In addition, the laser cutting process may cut a kerf target at a narrow kerf width, and thus the productivity thereof may be improved.

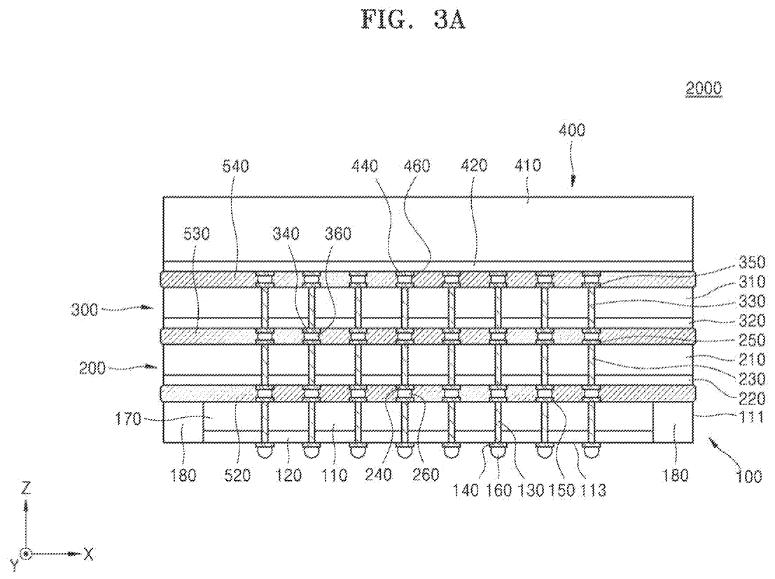

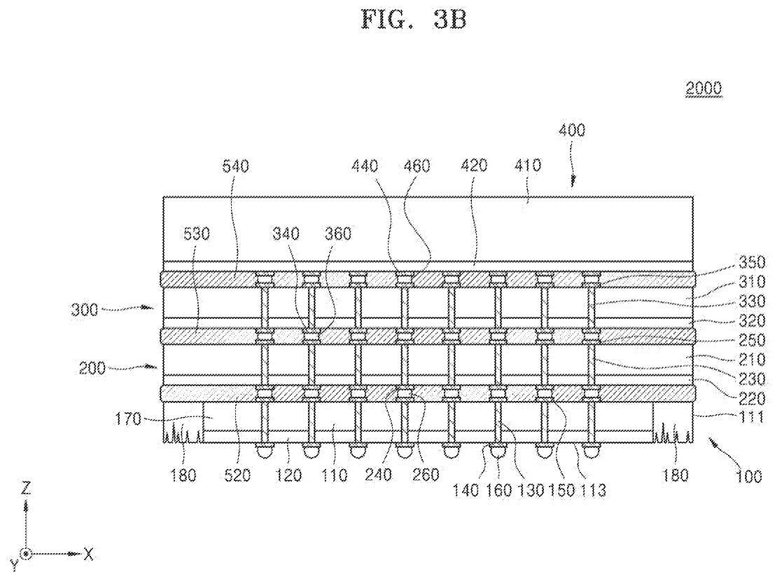

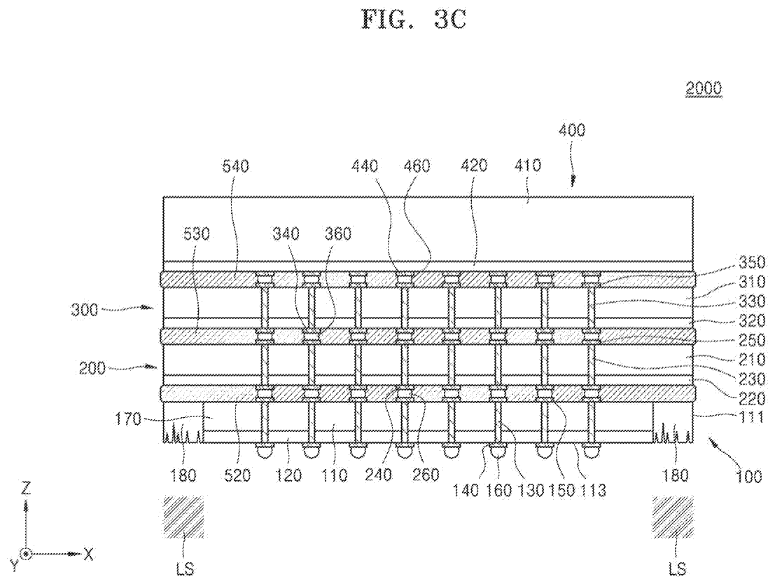

FIGS. 3A through 3C are cross-sectional views illustrating a semiconductor package and a method of manufacturing the semiconductor package, according to various embodiments.

In a semiconductor package 2000 described below with reference to FIGS. 3A through 3C, duplicate descriptions of the semiconductor package 1000 described with reference to FIGS. 1A through 2L are omitted for conciseness, and differences from the semiconductor package 1000 of FIGS. 1A through 2L are mainly given.

Referring to FIG. 3A, an interposer may be formed on a region less than the semiconductor chip in the semiconductor package 2000. In other words, the interposer may be arranged only on a partial region of the second surface 113 of the first semiconductor chip 100. The region, in which the interposer is not arranged, may be filled with an oxide layer 180. The oxide layer 180 may be formed in contact with the sidewall 170.

Referring to FIG. 3B, the surface treatment process may be performed to increase the surface roughness of at least a portion of the upper surface of the oxide layer 180 in the semiconductor package 2000. The surface treatment process may be selectively performed, before the sawing process is performed, only on a portion where the sawing process is to be performed. In some embodiments, the surface roughness may be improved from a nanometer level to a micrometer level by the surface treatment process, and thus may be improved by approximately 1000 times or more. In some embodiments, the surface treatment process may be performed by a dicing blade or a grinder. In the semiconductor package 2000 as illustrated in FIG. 1B, the portion 510b having not undergone the surface treatment process may be formed flat, but the portion 510a having undergone the surface treatment process may not be flat but have a rough surface.

Referring to FIG. 3C, the sawing process may be performed by using the laser LS on the resultant product obtained by performing the surface treatment process in FIG. 3B. Because the surface treatment process has been performed in FIG. 3B, the permeability of the oxide layer 180 may be decreased. Accordingly, the irradiating laser LS may stably process the oxide layer 180 from the surface thereof.

According to the technical idea of the present disclosure, because the oxide layer 180 is processed from the surface thereof, peeling or cracking due to the reduction in the interface adhesion force between the oxide layer 180 and a chip may be improved, and the singulation quality of the chip may be improved.

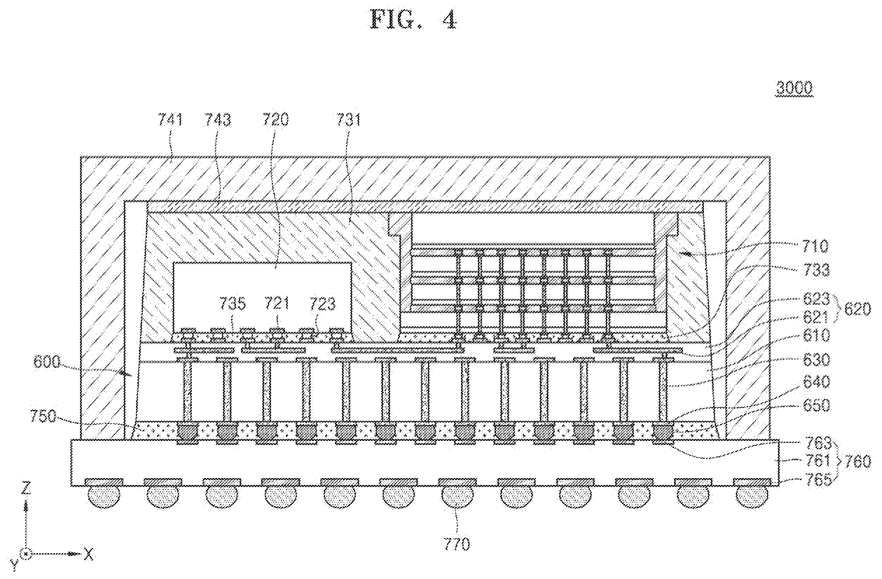

FIG. 4 is a cross-sectional view of a semiconductor package according to an embodiment.

Referring to FIG. 4 together with FIG. 1A, a semiconductor package 3000 may include a package substrate 760, an interposer 600 mounted on the package substrate 760, a first semiconductor device 710 mounted on the interposer 600, and a second semiconductor device 720 mounted on the interposer 600. The first semiconductor device 710 is illustrated as the semiconductor package 1000 illustrated in FIGS. 1A and 1B, but embodiments are not limited thereto and, in some embodiments, the semiconductor package 2000 illustrated in FIGS. 3A through 3C may be used as the first semiconductor device 710.

The interposer 600 may include a base layer 610, a redistribution structure 620, and an interposer through electrode 630.

The base layer 610 may include a semiconductor material, glass, ceramic, or plastic. In some embodiments, the base layer 610 may include silicon (Si), for example, a silicon wafer including crystalline silicon, polycrystalline silicon, or amorphous silicon.

The redistribution structure 620 may include a redistribution insulating layer 623 covering the first surface 111 of the base layer 610, and a conductive redistribution pattern 621 coated by the redistribution insulating layer 623. The conductive redistribution pattern 621 may include, for example, a plurality of wiring layers forming a multilayer structure and conductive vias extending in the vertical direction to electrically connect the plurality of wiring layers to each other. A portion of the plurality of wiring layers may be formed on an upper surface of the base layer 610 and form a pad connected to the interposer through electrode 630. Other portions of the plurality of wiring layers may be arranged on an upper side of the redistribution insulating layer 623, and may constitute a pad connected to a connection bump for electrical connection to semiconductor devices mounted on the interposer 600.

The interposer through electrode 630 may extend from the upper surface to a lower surface of the base layer 610 to penetrate the base layer 610. The interposer through electrode 630 may electrically connect the conductive redistribution pattern 621 of the redistribution structure 620 to a lower connection pad 640 arranged on the lower surface of the base layer 610. A board-interposer connection terminal 650 may be arranged on the lower connection pad 640.

The first semiconductor device 710 and the second semiconductor device 720 may be mounted apart from each other in the horizontal direction on the redistribution structure 620 of the interposer 600. The first semiconductor device 710 may be electrically connected to the second semiconductor device 720 via the conductive redistribution pattern 621 of the redistribution structure 620. The first semiconductor device 710 may be mounted on the interposer 600 via the first connection bump 160 arranged on a lower surface of the first semiconductor device 710, and the second semiconductor device 720 may be mounted on the interposer 600 via a chip connection bump 723 attached onto a pad 721 of the second semiconductor device 720. A first underfill material layer 733 for surrounding the first connection bump 160 may be arranged between the first semiconductor device 710 and the interposer 600, and a second underfill material layer 735 surrounding the chip connection bump 723 may be arranged between the second semiconductor device 720 and the interposer 600.

In FIG. 4, two semiconductor devices are illustrated as being mounted on the interposer 600 as an example, but embodiments are not limited thereto and, in some embodiments, the semiconductor package 3000 may include three or more semiconductor devices arranged on the interposer 600.

In some embodiments, the first semiconductor device 710 may include a memory device of a stacked type. For example, the first semiconductor device 710 may have a three-dimensional memory structure in which a plurality of chips are stacked. For example, the first semiconductor device 710 may be implemented based on the HBM or HMC standards.

The second semiconductor device 720 may include, for example, a system on chip, a CPU chip, a GPU chip, or an AP chip. The second semiconductor device 720 may execute applications, supported by the semiconductor package 3000, by using the first semiconductor device 710. For example, the second semiconductor device 720 may execute calculations specialized calculations by including at least one of a CPU, an AP, a GPU, a neural processing unit (NPU), a tensor processing unit (TPU), a vision processing unit (VPU), an image signal processing unit (ISP), and a digital signal processor (DSP).

The semiconductor package 3000 may further include a package molding layer 731 arranged on the interposer 600 and molding the first semiconductor device 710 and the second semiconductor device 720. The package molding layer 731 may include, for example, EMC. In exemplary embodiments, the package molding layer 731 may cover an upper surface of the interposer 600, sidewalls of the first semiconductor device 710, and sidewalls of the second semiconductor device 720, but may not cover an upper surface of the first semiconductor device 710.

The semiconductor package 3000 may further include a heat dissipation member 741 covering the upper surfaces of the first semiconductor device 710 and the second semiconductor device 720. The heat dissipation member 741 may include a heat dissipation plate, such as a heat slug and a heat sink. In some embodiments, the heat dissipation member 741 may surround the first semiconductor device 710, the second semiconductor device 720, and the interposer 600 on an upper surface of the package substrate 760.

In some embodiments, the semiconductor package 3000 may further include a thermal interface material (TIM) 743. The TIM 743 may be arranged between the heat dissipation member 741 and the first semiconductor device 710, and between the heat dissipation member 741 and the second semiconductor device 720.

The package substrate 760 may be electrically connected to the interposer 600 via the board-interposer connection terminal 650. An underfill material layer 750 may be arranged between the interposer 600 and the package substrate 760. The underfill material layer 750 may surround the board-interposer connection terminals 650.

The package substrate 760 may include a substrate base 761, and a substrate upper pad 763 and a substrate lower pad 765 respectively arranged on upper and lower surfaces of the substrate base 761. In some embodiments, the package substrate 760 may include a printed circuit board. For example, the package substrate 760 may include a multi-layer printed circuit board. The substrate base 761 may include at least one material of phenol resin, epoxy resin, and polyimide. The board-interposer connection terminal 650 may be connected to the substrate upper pad 763, and a package connection terminal 770 configured to electrically connect the external device to the semiconductor package 3000 may be connected to the substrate lower pad 765.

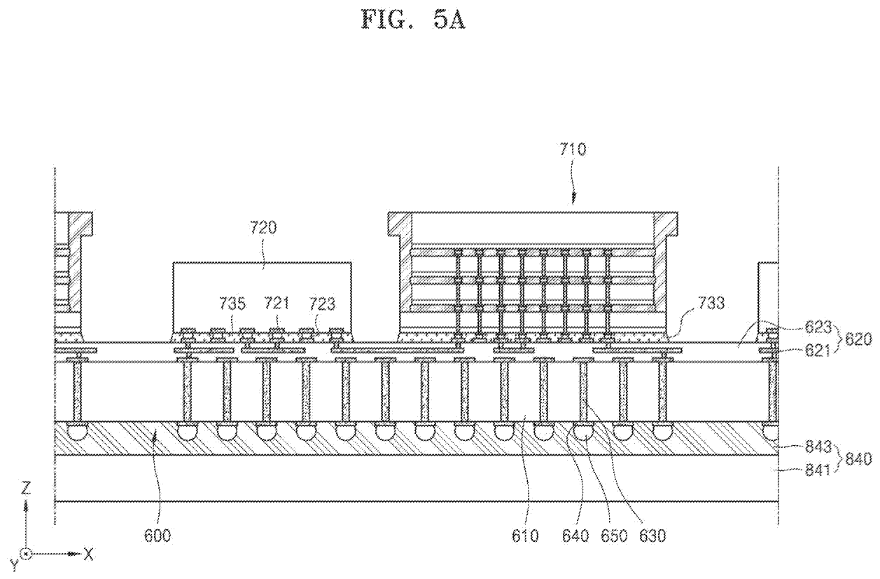

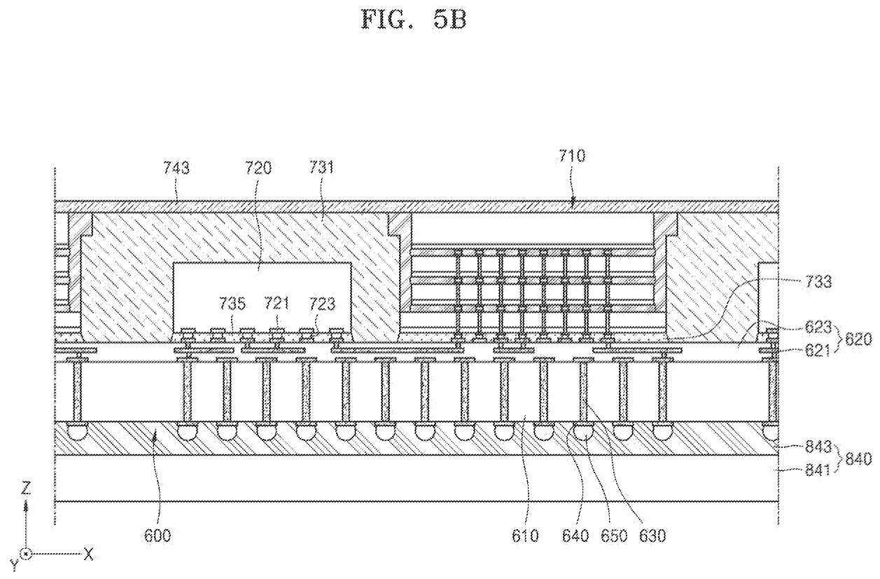

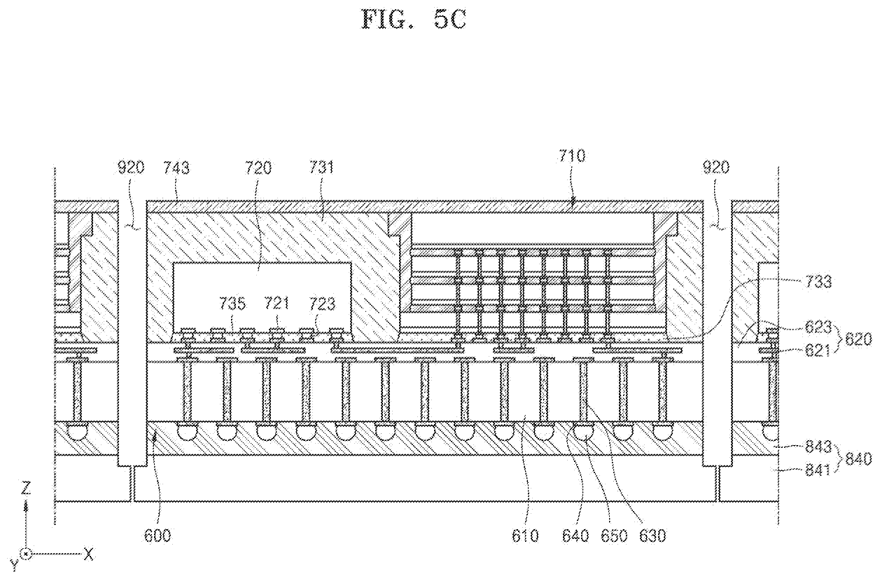

FIGS. 5A through 5C are cross-sectional views illustrating a method of manufacturing a semiconductor package, according to various embodiments. Hereinafter, a method of manufacturing the semiconductor package 3000 illustrated in FIG. 4 is described with reference to FIGS. 5A through 5C together with FIGS. 1A and 4.

Referring to FIG. 5A, the first semiconductor device 710 and the second semiconductor device 720 may be mounted on the interposer 600, on a wafer level, attached to a carrier substrate 840. The carrier substrate 840 may include a support substrate 841 and an adhesive material 843 on the support substrate 841. For example, the first semiconductor device 710 may be mounted on the interposer 600 via the first connection bump 160, and the second semiconductor device 720 may be mounted on the interposer 600 via the chip connection bump 723.

Referring to FIG. 5B, after the first semiconductor device 710 and the second semiconductor device 720 are mounted on the interposer 600, the first underfill material layer 733 filling a space between the first semiconductor device 710 and the interposer 600 and the second underfill material layer 735 filling a space between the second semiconductor device 720 and the interposer 600 may be formed, by performing an underfill process. Thereafter, on the interposer 600, the package molding layer 731 covering side surfaces of the first semiconductor device 710 and side surfaces of the second semiconductor device 720 may be formed. The package molding layer 731 may include, for example, EMC. After the package molding layer 731 is formed, the TIM 743 may be formed on the upper surface of the first semiconductor device 710, the upper surface of the second semiconductor device 720, and an upper surface of the package molding layer 731.

Referring to FIG. 5C, a sawing process of cutting the resultant product of FIG. 5B may be performed. By using the sawing process, the resultant product of FIG. 5B may be separated into a plurality of structures of a package size as illustrated in FIG. 4. After the sawing process is performed, the carrier substrate 840 may be removed.

In some embodiments, the sawing process may include a laser cutting process. In some embodiments, before the sawing process is performed, a surface treatment process may be performed by using a dicing blade, a grinder, or the like on a portion where the sawing process is to be performed.

In some embodiments, the surface treatment process may be performed to reduce the roughness of a surface and increase the permeability thereof. As a result, a portion having the surface treatment process performed thereon may have a rough surface which is not flat compared to a portion on which the surface treatment process has not been performed. The laser cutting process may be performed around a portion on which the surface treatment process has been performed. By using the laser cutting process, as illustrated in FIG. 5C, a cutting region 920 of a rectangular shape may be formed. By using the laser cutting process, the sidewalls of the package molding layer 731 and/or sidewalls of the interposer 600 may be formed to have an ‘L’ shape in the vertical direction.

Thereafter, as illustrated in FIG. 4, the interposer 600 may be mounted on the package substrate 760. The interposer 600 may be mounted on the package substrate 760 via the board-interposer connection terminal 650. An underfill material layer 750 surrounding the board-interposer connection terminal 650 may be formed between the interposer 600 and the package substrate 760. Next, the heat dissipation member 741 surrounding the first semiconductor device 710, the second semiconductor device 720, and the interposer 600 may be attached onto the upper surface of the package substrate 760 and the TIM 743.

As described above, embodiments have been illustrated in the drawings. While various embodiments have been described herein with reference to specific terms, it should be understood that the various embodiments have been used only for the purpose of describing the technical idea of the present disclosure and not for limiting the scope of the present disclosure as defined in the claims. Thus, those with ordinary skill in the art will appreciate that various modifications and equivalent embodiments are possible without departing from the scope of the present disclosure. Accordingly, the true scope of protection should be determined by the technical idea of the following claims.

While various embodiments have been particularly shown and described with reference to the drawings, it will be understood that various changes in form and details may be made therein without departing from the spirit and scope of the following claims.

What is claimed is:

1. A semiconductor package comprising:
a first semiconductor chip including a first surface and a second surface opposite to the first surface;
at least one second semiconductor chip stacked on the first surface of the first semiconductor chip; and
a molding layer contacting the first surface of the first semiconductor chip and a sidewall of the at least one second semiconductor chip,
wherein the molding layer comprises:
a first sidewall from a lower end of the first semiconductor chip to a first height in a first direction perpendicular to the first surface of the first semiconductor chip;
a second sidewall from the first height to a second height in the first direction; and
a flat surface that extends from the first height in a second direction that is parallel with the first surface of the first semiconductor chip.

2. The semiconductor package of claim 1, wherein the second height is located at a level higher than the first height.

3. The semiconductor package of claim 2, wherein the second height corresponds to a height of an upper surface of the molding layer.

4. The semiconductor package of claim 1, wherein the flat surface perpendicularly contacts an uppermost end of the first sidewall, and perpendicularly contacts a lowermost end of the second sidewall.

5. The semiconductor package of claim 1, wherein at least a portion of an upper surface of the molding layer is not flat.

6. The semiconductor package of claim 5, wherein the at least a portion of the upper surface of the molding layer corresponds to a scribe lane portion of a semiconductor chip periphery.

7. The semiconductor package of claim 5, wherein the at least a portion of the upper surface of the molding layer has been treated by a surface treatment performed by a dicing blade or a grinder.

8. The semiconductor package of claim 5, wherein a first portion of the upper surface of the molding layer is not flat and a second portion of the upper surface of the molding layer is flat, and
the first portion has a surface roughness 1000 times or more than a surface roughness of the second portion.

9. The semiconductor package of claim 1, wherein the first semiconductor chip comprises a plurality of first through electrodes, and
the at least one second semiconductor chip comprises a plurality of second through electrodes that are electrically connected to the plurality of first through electrodes, respectively.

10. The semiconductor package of claim 1, wherein the molding layer comprises a light-transmitting film.

11. A semiconductor package comprising:
a first semiconductor chip including a first surface and a second surface opposite to the first surface, the first semiconductor chip including a plurality of first through electrodes;
at least one second semiconductor chip stacked on the first surface of the first semiconductor chip, and including a plurality of second through electrodes that are electrically connected to the plurality of first through electrodes, respectively;
an interposer arranged on a first region of the second surface of the first semiconductor chip; and
an oxide layer arranged in a second region of the second surface of the first semiconductor chip, where the interposer is not arranged,
wherein the oxide layer contacts with a sidewall of the interposer.

12. The semiconductor package of claim 11, wherein at least a portion of an upper surface of the oxide layer is not flat.

13. The semiconductor package of claim 12, wherein the at least a portion of the upper surface of the oxide layer has been treated by a surface treatment performed by a dicing blade or a grinder.

14. The semiconductor package of claim 12, wherein a first portion of the upper surface of the oxide layer is not flat and a second portion of the upper surface of the oxide layer is flat, and
the first portion has a surface roughness 1000 times or more than a surface roughness of the second portion.

15. The semiconductor package of claim 11, wherein a height of an upper surface of the oxide layer is at a same level as a height of an upper surface of the interposer.

16. The semiconductor package of claim 11, wherein the interposer has a rectangular shape, and
the oxide layer has a rectangular ring shape that extends along a periphery of the interposer.

17. The semiconductor package of claim 11, wherein the oxide layer comprises a light-transmitting layer.

18. A semiconductor package comprising:
a package substrate;
an interposer on the package substrate;
a first semiconductor device mounted on the interposer;
a second semiconductor device mounted on the interposer and spaced apart from the first semiconductor device, the second semiconductor device being electrically connected to the first semiconductor device via the interposer; and
a package molding layer arranged on the interposer, and covering a sidewall of the first semiconductor device and a sidewall of the second semiconductor device,
wherein the first semiconductor device comprises a first semiconductor chip including a first surface and a second surface opposite to the first surface, at least one second semiconductor chip mounted on the first semiconductor chip, and a molding layer covering the first surface of the first semiconductor chip and a sidewall of the at least one second semiconductor chip,
wherein the molding layer comprises a first sidewall from a lower end of the first semiconductor chip to a first height in a first direction that is perpendicular to the first surface of the first semiconductor chip, a second sidewall from the first height to a second height in the first direction, and a flat surface that extends at the first height in a second direction that is parallel with the first surface of the first semiconductor chip.

19. The semiconductor package of claim 18, wherein a sidewall of the package molding layer is connected to a sidewall of the interposer.

20. The semiconductor package of claim 18, wherein the molding layer comprises a light-transmitting layer.
